(19) United States
(12) Patent Application Publication
(10) Pub. No.: US 2025/0169345 A1
(43) Pub. Date: May 22, 2025

(54) PROCESSING DEVICE

(71) Applicant: SAMSUNG DISPLAY CO., LTD., YONGIN-SI (KR)

(72) Inventor: JAESUNG LIM, Yongin-si (KR)

(21) Appl. No.: 18/758,816

(22) Filed: Jun. 28, 2024

(30) Foreign Application Priority Data
Nov. 20, 2023 (KR) 10-2023-0160471

(51) Int. Cl. H10K 71/00; H10K 71/40

(52) U.S. Cl. CPC H10K 71/811; H10K 71/40

(57) ABSTRACT

A processing device for processing a substrate includes a vacuum chamber including a processing space including an inner wall disposed adjacent to the processing space and an outer wall disposed on and spaced apart from the inner wall, and a plurality of heaters disposed between the inner wall and the outer wall.

### CROSS-REFERENCE TO RELATED APPLICATION

This application claims priority under 35 U.S.C. § 119 to Korean Patent Application No. 10-2023-0160471, filed on Nov. 20, 2023, in the Korean Intellectual Property Office, the content of which is incorporated by reference herein in its entirety.

### TECHNICAL FIELD

The disclosure relates to a processing device. More specifically, the disclosure relates to a processing device for processing a substrate of a display device.

### DISCUSSION OF RELATED ART

As information technology develops, the importance of a display device as a means for communicating information to a user is increasing. Various types of display devices are widely used in various fields. For example, a display device may be implemented as a liquid crystal display device (“LCD”), an organic light-emitting display device (“OLED”), a plasma display device (“PDP”), or a quantum dot display device.

Among the different types of display devices, a display device including a light-emitting device including an organic material has been proposed. An organic material layer of the light-emitting device may be formed through an inkjet process.

The inkjet process may include a process of ejecting ink, a process of drying the ink, and a process of completing a thin film through curing of the ink. The drying process and/or the curing process may be performed within a chamber.

### SUMMARY

Embodiments of the disclosure provide a processing device that may reduce or eliminate foreign material of a thin film.

A processing device for processing a substrate according to an embodiment of the disclosure includes a vacuum chamber including a processing space including an inner wall disposed adjacent to the processing space and an outer wall disposed on and spaced apart from the inner wall, and a plurality of heaters disposed between the inner wall and the outer wall.

In an embodiment, the processing device may further include a first remover disposed in the processing space of the vacuum chamber. The first remover may include a mesh network and an absorbent disposed in the mesh network.

In an embodiment, the absorbent may include at least one of charcoal or a porous material.

In an embodiment, the first remover may adsorb an organic material.

In an embodiment, the processing space may be defined by a first side and a second side facing each other in a first direction, at least one side wall may extend between the first side and the second side, and the first remover may be disposed on each of the first side and the second side facing each other in the first direction in the vacuum chamber.

In an embodiment, the processing space may be defined by a first side and a second side facing each other in a first direction, a first side wall and a second side wall facing a second direction crossing the first direction, a third side wall and a fourth side wall facing a third direction crossing each of the first direction and the second direction, the plurality of heaters may include a first heater and a second heater, the first heater may be disposed adjacent to the first side, and the second heater may be disposed adjacent to the second side.

In an embodiment, the first heater may be configured to apply a first heating amount and the second heater may be configured to apply a second heating amount less than the first heating amount.

In an embodiment, the processing device may further include a second remover disposed outside the vacuum chamber, and a connection pipe connected to the second remover, penetrating the outer wall and the inner wall of the vacuum chamber, and providing a path for fluid in the processing space to move from the processing space.

In an embodiment, the fluid may include an organic material.

In an embodiment, the first side of the vacuum chamber may be disposed on the second side, and the second remover may be connected to the connection pipe adjacent to the second side.

A processing device for processing a substrate according to an embodiment of the disclosure includes a vacuum chamber including a processing space defined by a first side and a second side facing each other in a first direction, a first side wall and a second side wall facing a second direction crossing the first direction, a third side wall and a fourth side wall facing a third direction crossing each of the first direction and the second direction, wherein each of the first side wall, the second side wall, the third side wall, and the fourth side wall include an inner wall disposed adjacent to the processing space and an outer wall disposed on and spaced apart from the inner wall, a plurality of heaters disposed between the inner wall and the outer wall, and a stage disposed between the first side and the second side in the processing space.

In an embodiment, the processing device may further include a first remover disposed in the processing space of the vacuum chamber. The first remover may include a mesh network and an absorbent disposed in the mesh network.

In an embodiment, the absorbent may include at least one of charcoal or a porous material.

In an embodiment, the first remover may adsorb an organic material.

In an embodiment, the first remover may be disposed on each of the first side and the second side facing each other in the first direction in the vacuum chamber.

In an embodiment, the plurality of heaters may include a first heater and a second heater, the first heater may be disposed adjacent to the first side, the second heater may be disposed adjacent to the second side, and the first heater may be configured to apply a first heating amount and the second heater may be configured to apply a second heating amount different than the first heating amount.

In an embodiment, the processing device may further include a second remover disposed outside the vacuum chamber and a connection pipe connected to the second remover, penetrating the outer wall and the inner wall of the vacuum chamber, and providing a path for fluid in the processing space may move from the processing space.

In an embodiment, the first side of the vacuum chamber may be disposed on the second side, and the second remover may be connected to the connection pipe adjacent to the second side.

A processing device for processing a substrate according to an embodiment of the disclosure includes a vacuum chamber including a processing space defined by a first side and second side facing each other in a first direction and at least one side wall extending between the first side and the second side, the at least one side wall including an inner wall disposed adjacent to the processing space and an outer wall disposed on and spaced apart from the inner wall, and a plurality of heaters disposed between the inner wall and the outer wall and including a first heater disposed adjacent to the first side and a second heater disposed adjacent to the second side.

In an embodiment, a first remover may be disposed on each of the first side and the second side facing each other in the first direction in the vacuum chamber, a second remover may be disposed outside the vacuum chamber, and a connection pipe may be connected to the second remover and may penetrate the outer wall and the inner wall of the vacuum chamber.

A processing device for processing a substrate according to embodiments of the disclosure includes a vacuum chamber including a processing space defined by a first side and second side facing each other in a first direction and at least one side wall extending between the first side and the second side, the at least one side wall including an inner wall disposed adjacent to the processing space and an outer wall disposed on and spaced apart from the inner wall, and a plurality of heaters disposed between the inner wall and the outer wall and including a first heater disposed adjacent to the first side and a second heater disposed adjacent to the second side.

In addition, the processing device may include a first remover disposed on each of the first side and the second side facing each other in the first direction in the vacuum chamber, a second remover disposed outside the vacuum chamber, and a connection pipe connected to the second remover, penetrating the outer wall and the inner wall of the vacuum chamber.

A processing device according to embodiments of the disclosure includes a vacuum chamber including a processing space defined by a first side and second side facing each other in a first direction, a first side wall and a second side wall facing a second direction crossing the first direction, a third side wall and a fourth side wall facing a third direction crossing each of the first direction and the second direction, wherein each of the first side wall, the second side wall, the third side wall, and the fourth side wall including an inner wall disposed adjacent to the processing space and an outer wall disposed on and spaced apart from the inner wall, and a plurality of heaters disposed between the inner wall and the outer wall. Accordingly, the processing device may remove a foreign material generated during thin film formation by heating.

In addition, the processing device may further include a first remover disposed in the processing space of the vacuum chamber. Accordingly, the processing device may remove the foreign material in a liquid state by adsorbing.

In addition, the processing device may further include a second remover disposed outside the vacuum chamber and a connection pipe connected to the second remover, penetrating the outer wall and the inner wall of the vacuum chamber, and providing a path for liquid in the processing space from the processing space to the second remover. Accordingly, the processing device may exhaust the foreign material in a gaseous state.

In addition, the plurality of heaters may include a first heater and a second heater. The first heater may be disposed adjacent to the first side. The second heater may be disposed adjacent to the second side. A first heating amount of the first heater may be greater than a second heating amount of the second heater. Accordingly, the foreign material may be removed along the fluid flow due to a temperature difference.

### BRIEF DESCRIPTION OF THE DRAWINGS

The accompanying drawings, which are included to provide a further understanding of the present invention, illustrate embodiments of the disclosure together with the description thereof, in which:

FIG. 1 is a cross-sectional view illustrating a processing device according to embodiments of the disclosure;

FIG. 2 is a view illustrating a first remover included in the processing device of FIG. 1;

FIG. 3 is a view illustrating the second remover included in the processing device of FIG. 1;

FIG. 4 is a view illustrating the fluid flow in the processing device according to a comparative embodiment;

FIG. 5 is a view illustrating the substrate disposed in the processing device of FIG. 4;

FIG. 6 is a view illustrating a sub pixel manufactured by the processing device of FIG. 4;

FIG. 7 is a view illustrating the fluid flow in the processing device of FIG. 1;

FIG. 8 is a view illustrating the substrate disposed in the processing device of FIG. 1;

FIG. 9 is a view illustrating the sub pixel manufactured by the processing device of FIG. 1;

FIG. 10 is a view illustrating an effect of the processing device of FIG. 1; and

FIG. 11 is a view illustrating a display device formed using the processing device of FIG. 1.

### DETAILED DESCRIPTION

Illustrative, non-limiting embodiments of the disclosure will be more clearly understood from the following detailed description in conjunction with the accompanying drawings. The same reference numerals are used for the same components in the drawings, and redundant descriptions of the same components may be omitted.

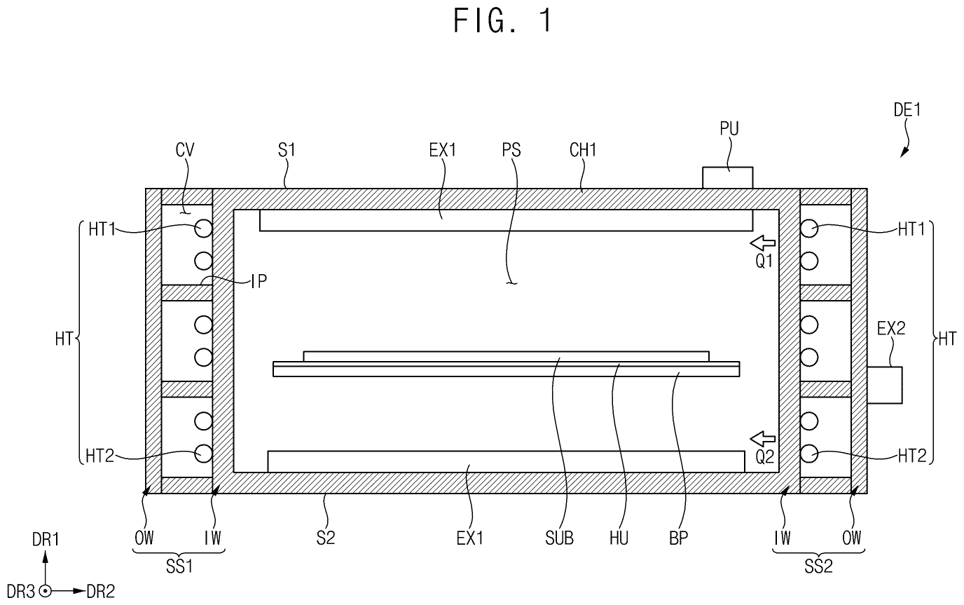

FIG. 1 is a cross-sectional view illustrating a processing device according to embodiments of the disclosure.

Referring to FIG. 1, in an embodiment, a processing device DE1 may include a vacuum chamber CH1, a stage BP, a pressure reducer PU, a heating unit HU, a plurality of heaters HT, a first remover EX1, and a second remover EX2.

In an embodiment, the vacuum chamber CH1 may provide a sealed processing space PS. To this end, in an embodiment, the vacuum chamber CH1 may include one or more inner surfaces. For example, the vacuum chamber CH1 may include a first side S1 and a second side S2. In an embodiment, the first side S1 and the second side S2 may face each other in a first direction DR1. In an embodiment, at least one side wall may extend between the first side S1 and the second side S2. For example, a first side wall SS1, a second side wall SS2, a third side wall (not shown), and a fourth side wall (not shown) may extend between the first side S1 and the second side S2.

The first side S1 may positioned on the second side S2. The first side wall SS1 and the second side wall SS2 may face each other in a second direction DR2. The third side wall and the fourth side wall may face each other in a third direction DR3. In an embodiment, the first side wall SS1 and the second side wall SS2 may be a left side wall and a right side wall, respectively, and the third side wall and the fourth side wall may be a front side wall and a rear side wall, respectively.

The second direction DR2 may cross the first direction DR1. In addition, the third direction DR3 may cross each of the first direction DR1 and the second direction DR2. For example, the second direction DR2 may be a X direction, the third direction DR3 may be a Y direction, and the first direction DR1 may be a Z direction. However, the disclosure is not limited thereto.

The inner surface may be a surface of a wall of the vacuum chamber CH1. In an embodiment, one or more of the first side wall SS1, the second side wall SS2, the third side wall, and the fourth side wall may include an inner wall IW and an outer wall OW. For example, each of the first side wall SS1, the second side wall SS2, the third side wall, and the fourth side wall may include an inner wall IW and an outer wall OW. The inner wall IW may be adjacent to the processing space PS, and the outer wall OW may be disposed on and spaced apart from the inner wall IW. In other words, the inner wall IW and the outer wall OW may be positioned sequentially in a direction from the sealed processing space PS of the vacuum chamber CH1 toward an outside.

The vacuum chamber CH1 may maintain a normal pressure atmosphere, a vacuum atmosphere, or a vacuum dry atmosphere in which a specific gas may be injected into the sealed processing space PS. For example, the gas may include nitrogen. However, the disclosure is not limited thereto.

The vacuum chamber CH1 may accommodate a substrate SUB. That is, the processing device DE1 may be device for processing a substrate. In an embodiment, an ink may be deposited on the substrate SUB.

The substrate SUB may include a transparent or opaque material. In an embodiment, the substrate SUB may have rigid characteristics. For example, the substrate SUB having the rigid characteristic may include glass, metal, or the like.

In an embodiment, the ink may include a light-emitting material and a solvent. In an embodiment, the ink may include one or more of various organic materials. In an embodiment, the light-emitting material may include an organic material. For example, an organic material of the light-emitting material may include a quantum dot. The quantum dots may emit light with a unique wavelength. In an embodiment, the quantum dot may include a semiconductor nanocrystal material. Embodiments of the semiconductor nanocrystal material may include group IV nanocrystals, group II-VI compound nanocrystals, group III-V compound nanocrystals, group IV-VI nanocrystals, or the like. These materials may be used alone or in combination with each other. In an embodiment, the quantum dot may have a core-shell structure. The core may include the nanocrystals, and the shell may surround the core. The shell may include a material that may serve as a protecting layer for maintaining a semiconductor property. For example, the shell may prevent or reduce chemical denaturation of the core. The shell may include a material that may serve as a charging layer for providing electrophoretic property to the quantum dot.

In an embodiment, the light-emitting material may include an organic material. However, the disclosure is not limited thereto. For example, the light-emitting material may include an inorganic material.

As described herein, the ink may include the solvent and the light-emitting material. In an embodiment, the solvent may be removed from the processing space PS. A first portion of solvent may be removed from the ink through the drying process, and a second portion of the solvent may be removed from the ink through the curing process. Accordingly, the thin film may be formed on the substrate SUB.

The stage BP may be a support structure. For example, the substrate SUB may be disposed on the stage BP, and the stage BP may support the substrate SUB inside the vacuum chamber CH1. In an embodiment, the stage BP and the substrate SUB on the stage BP may be disposed between the first surface S1 and the second surface S2 of the vacuum chamber CH1. In an embodiment, a driving device may be connected to the stage BP. The driving device may move the stage BP up/down (e.g., in the first direction DR1). In an embodiment, the driving device may be an actuator, pneumatic cylinder, or the like.

In an embodiment, the pressure reducer PU may be connected to the vacuum chamber CH1. The pressure reducer PU may discharge a gas from the vacuum chamber CH1. For example, the pressure reducer PU may discharge the gas inside the vacuum chamber CH1 to the outside of the vacuum chamber CH1. In discharging the gas, the pressure reducer PU may lower an internal pressure of the vacuum chamber CH1. In an embodiment, the pressure reducer PU may include a dry pump, a turbo pump, or the like. The pressure reducer PU may discharge the gas and a substance evaporated from the ink on the substrate SUB to the outside of the vacuum chamber CH1. For example, the pressure reducer PU may discharge the solvent from the vacuum chamber CH1.

In an embodiment, the heating unit HU may be disposed on the stage BP. For example, the heating unit HU may be disposed between the stage BP and the substrate SUB. The heating unit HU may generate heat, which may heat the substrate SUB. Evaporation of the solvent from the ink on the substrate SUB may be aided by the heat. In an embodiment, the heating unit HU may include a resistor, a heat ray, a heat source (e.g., infrared rays, or the like.), or the like. These may be used alone or in combination with each other. However, the disclosure is not limited thereto.

In an embodiment, the heating unit HU may include, or may be connected to a control unit. In an embodiment, the control unit may include a programmable logic device (“PLD”) such as a field programmable gate array (“FPGA”), an application specific integrated circuit (“ASIC”), or a computer including a program. These may be used alone or in combination with each other. However, the disclosure is not limited thereto.

The control unit may control an operation of one or more other components. For example, the control unit may control a temperature of the heating unit HU. In another example, the control unit may control the internal pressure of the vacuum chamber CH1.

In an embodiment, the plurality of heaters HT may be disposed between the inner wall IW and the outer wall OW of the vacuum chamber CH1. For example, the plurality of heaters HT may be disposed directly on the inner wall IW, between the inner wall IW and the outer wall OW of the vacuum chamber CH1. However, the disclosure is not limited thereto. For example, the plurality of heaters HT may be supported at a middle portion between the inner wall IW the outer wall OW of the vacuum chamber CH1.

In an embodiment, the plurality of heaters HT may include a resistor, a heat ray, a heat source (e.g., infrared rays, or the like.), or the like. These may be used alone or in combination with each other. However, the disclosure is not limited thereto.

In an embodiment, the plurality of heaters HT may be connected to the control unit. The control unit may control a temperature of each of the plurality of heaters HT. For example, the plurality of heaters HT may apply a same heating amount or may apply different heating amounts.

In an embodiment, the plurality of heaters HT may include a first heater HT1 and a second heater HT2. The first heater HT1 may be disposed adjacent to the first surface S1 and the second heater HT2 may be disposed adjacent to the second surface S2.

Each of the plurality of heaters HT may apply different heating amounts. For example, in an embodiment, the first heater HT1 and the second heater HT2 may apply different heating amounts. For example, the first heater HT1 may have a first heating amount Q1, and the second heater HT2 may have a second heating amount Q2. In an embodiment, each of the plurality of heaters HT may have a temperature of between about 60 degrees and about 300 degrees. However, the disclosure is not limited thereto.

In an embodiment, the first heating amount Q1 may be greater than the second heating amount Q2. In other words, the first heater HT1 disposed at an upper portion of the vacuum chamber CH1 may have a greater temperature than the second heater HT2 disposed at a lower portion of the vacuum chamber CH1. For example, the first heater HT1 may be about 300 degrees, and the second heater HT2 may be about 150 degrees. Accordingly, in the processing space PS of the vacuum chamber CH1, a fluid flow directed from an upper part of the processing space PS to a lower part of the processing space PS may be formed.

In an embodiment, the first remover EX1 may be disposed in the processing space PS of the vacuum chamber CH1. For example, the first remover EX1 may be disposed on at least one of the first side S1 or the second side S2. As described herein, the first side S1 and the second side S2 may face each other in the first direction DR1.

In processing the substrate SUB (e.g., the drying process and/or the curing process), the solvent and/or the light-emitting material (hereinafter referred to as “a foreign material”) may move toward the upper part of the substrate SUB or to the lower part of the substrate SUB. The first remover EX1 may remove the foreign material moving to the upper part and/or lower part of the substrate SUB. Specifically, the foreign material moving to the upper part of the substrate SUB may be removed by the first remover EX1 disposed on the first surface S1. The foreign material moving to the lower part of the substrate SUB may be removed by the first remover EX1 disposed on the second surface S2.

However, the disclosure is not limited thereto. For example, when an exhaust device is disposed on a first side of the substrate SUB (e.g., the upper part of the substrate SUB), the first remover EX1 may be disposed on a second side of the substrate SUB (e.g., the lower part of the substrate SUB) opposite to the first side of the substrate SUB. Specifically, the foreign material moving to the first side of the substrate SUB may be removed by the exhaust device disposed on the first side S1. The foreign material moving to the second side of the substrate SUB may be removed by the first remover EX1 disposed on the second side S2.

In an embodiment, the first remover EX1 may remove the foreign material, which may be a in liquid form. However, the disclosure is not limited thereto.

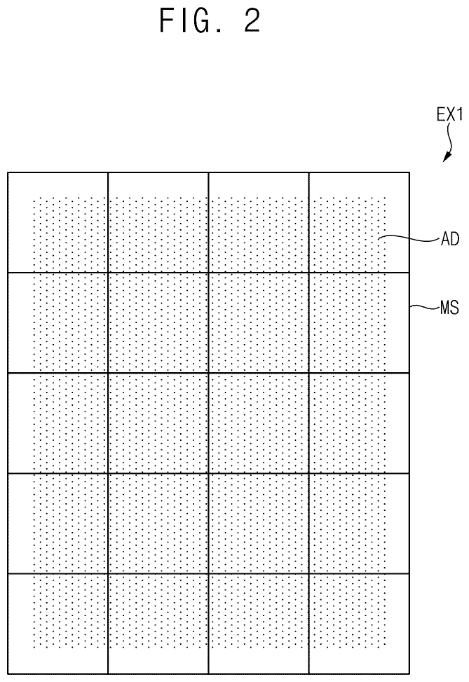

The first remover EX1 may be installed in the vacuum chamber CH1. The first remover EX1 may be removed from the vacuum chamber CH1. To this end, in an embodiment, the first remover EX1 may include a mesh network (see mesh network MS of FIG. 2) and an adsorbent (see adsorbent AD of FIG. 2). In an embodiment, the absorbent AD may be disposed inside the mesh network MS.

The foreign material may be deposited in the first remover EX1 during the processing (e.g., the drying process and/or the curing process) of the substrate SUB. Accordingly, contamination of the substrate SUB by the foreign material may be reduced or prevented. In an embodiment, the first remover EX1 may be periodically replaced or recharged. For example, in the first remover EX1, the absorbent may be replaced, or the mesh network and the absorbent may be replaced simultaneously. A detailed description of the first remover EX1 is described with reference to FIG. 2.

In an embodiment, the processing device DE1 may further include the second remover EX2. In an embodiment, the second remover EX2 may be disposed outside the vacuum chamber CH1. For example, the second remover EX2 may be disposed adjacent to one side (e.g., the second side SS2) of the vacuum chamber CH1. However, the disclosure is not limited thereto. For example, the second remover EX2 may be disposed adjacent to the other side (e.g., the first side SS1, the third side, or the fourth side) of the vacuum chamber CH1.

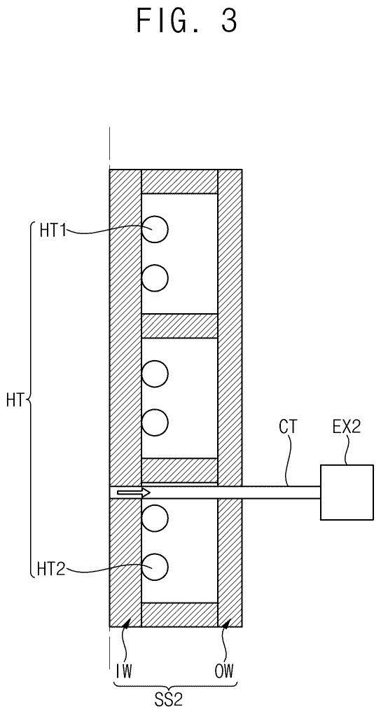

Referring to FIG. 3, in an embodiment, the second remover EX2 may be connected to a connection pipe CT. The connection pipe CT may be disposed adjacent to the second heater HT2. As described herein, the first heater HT1 positioned at an upper portion of the vacuum chamber CH1 may have a greater temperature than the second heater HT2 positioned at a lower portion of the vacuum chamber CH1. In other words, the second remover EX2 may be connected to the connection pipe disposed at a lower portion of the vacuum chamber CH1. However, the disclosure is not limited thereto. For example, the second remover EX2 may be connected to the connection pipe CT disposed at a lower surface (e.g., the second surface S2) of the vacuum chamber CH1.

In the processing (e.g., the drying process and/or the curing process) the substrate SUB, the solvent and/or the light-emitting material (hereinafter referred to as “foreign material”) may move to the side of the substrate SUB. The second remover EX2 may remove the foreign material moving to the side of the substrate SUB. The foreign material moving to the side of the substrate SUB along the fluid flow formed in the processing space PS may be exhausted to the outside of the vacuum chamber CH1 by and/or through the second remover EX2. A detailed description of the second remover EX2 is described with reference to FIG. 3.

In an embodiment, the second remover EX2 may remove the foreign material in gaseous form. However, the disclosure is not limited thereto.

FIG. 1 is exemplary, and the processing device DE1 may further include additional components. In addition, some components of the substrate processing apparatus DE1 may be omitted. In addition, some components of the processing device DE1 may be changed.

In an embodiment, and referring to FIG. 1, the plurality of heaters HT may include the first heater HT1 and the second heater HT2, however, the plurality of heaters HT may include three or more heaters. For embodiment, each of the three heaters may heat the first heating amount Q1, the second heating amount Q2, and a third heating amount, respectively. The first heating amount Q1, the second heating amount Q2, and the third heating amount may be the same heating amount, or two or more heating amounts. For example, the third heating amount may be different from both the first heating amount Q1 and the second heating amount Q2.

In an embodiment, an intermediate partition wall IP may be further included between the inner wall IW and the outer wall OW. For example, a plurality of intermediate partition walls IP may extend in the second direction between the inner wall IW and the outer wall OW. The intermediate partition wall IP may divide a space between the inner wall IW and the outer wall OW into a plurality of cavities CV. Each cavity CV may house one or more heaters HT. For example, an upper cavity may include the first heater HT1 and a lower cavity may include the second heater HT2. A cavity CV may include different heaters. For example, a cavity CV disposed at a middle portion of the processing space PS of the vacuum chamber CH1 may include one or more first heaters HT1 and one or more second heaters HT2. However, the disclosure is not limited thereto. The intermediate partition wall IP may be disposed to improve a structural strength of the outer wall OW and/or the inner wall IW.

FIG. 2 is a view illustrating a first remover EX1 included in the processing device of FIG. 1.

Referring to FIG. 2, the first remover EX1 may include the mesh network MS and the adsorbent AD. In an embodiment, the adsorbent AD may be disposed inside the mesh network MS.

The mesh network MS may have a structure with a plurality of holes defined in a layer. The mesh network MS may have a structure may have one or more layers, and each layer may have a plurality of holes. Accordingly, the foreign material may flow into the structure of the mesh network MS through the plurality of holes.

In an embodiment, the mesh network MS may include a steel use stainless (“SUS”), or the like. For example, each layer may be formed of a SUS including a plurality of holes. However, the disclosure is not limited thereto.

In an embodiment, the adsorbent AD may include charcoal, a porous material, or the like. These materials may be used alone or in combination with each other. However, the disclosure is not limited thereto. In an embodiment, the adsorbent AD may be disposed between layers of the mesh network MS.

The first remover EX1 may remove the foreign material generated during the processing (e.g., the drying process and/or the curing process) of the substrate SUB. In an embodiment, the first remover EX1 may remove an organic material. As described herein, an organic material may be in liquid form. However, the disclosure is not limited thereto. An organic material may be adsorbed by the adsorbent AD and removed from the processing space PS.

FIG. 3 is a view illustrating the second remover included in the processing device of FIG. 1.

Referring to FIG. 1, FIG. 2, and FIG. 3, the processing device DE1 may further include the connection pipe CT. In an embodiment, the second remover EX2 may be disposed outside the vacuum chamber CH1. In an embodiment, the connection pipe CT may connect between the vacuum chamber CH1 and the second remover EX2.

In an embodiment, the second remover EX2 may include a pump that provides suction pressure. The pump may exhaust the foreign material in the processing space PS to the outside of the vacuum chamber CH1 via the connection pipe CT. However, the disclosure is not limited thereto.

The connection pipe CT may penetrate the outer wall OW and the inner wall IW of the vacuum chamber CH1. Accordingly, the connection pipe CT may provide a path through which the foreign material may move from the processing space PS to the second remover EX2.

The second remover EX2 may remove the foreign material generated during the processing (e.g., the drying process and/or the curing process) of the substrate SUB. In an embodiment, the second remover EX2 may remove an organic material. As described herein, an organic material may be in gaseous form. However, the disclosure is not limited thereto. An organic material may be removed from the processing space PS by the suction pressure of the second remover EX2.

As described above, in an embodiment, the second remover EX2 may be connected to a connection pipe disposed adjacent to the second heater HT2. In other words, the second remover EX2 may be connected to a connection pipe disposed at a low temperature position in the vacuum chamber CH1. However, the disclosure is not limited thereto. For example, the second remover EX2 may be connected to a connection pipe disposed at the lower part (e.g., second surface S2) of the vacuum chamber CH1. Accordingly, the foreign material stagnating in the lower part of the vacuum chamber CH1 may be discharged to the outside of the vacuum chamber CH1.

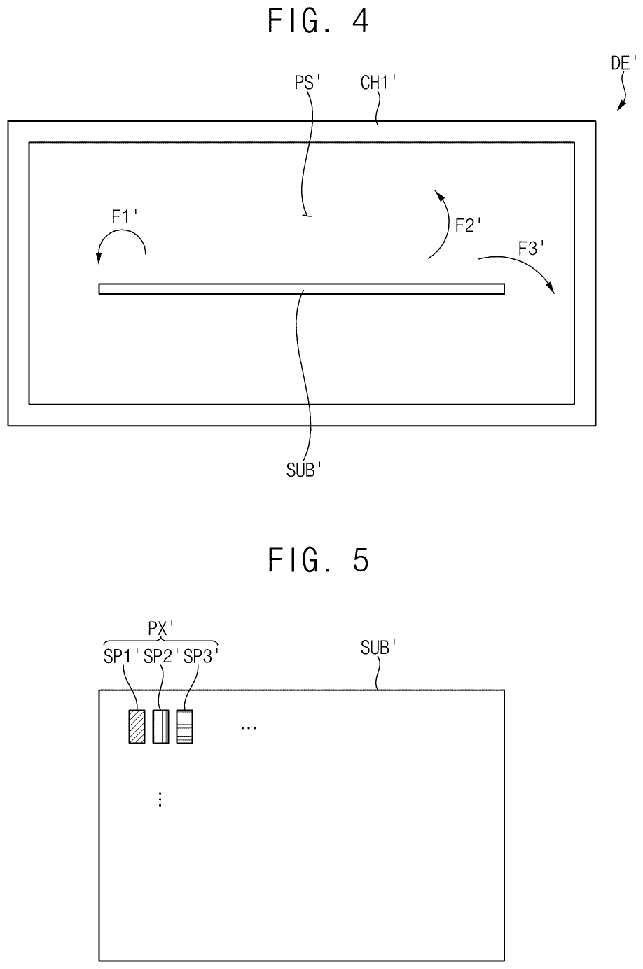

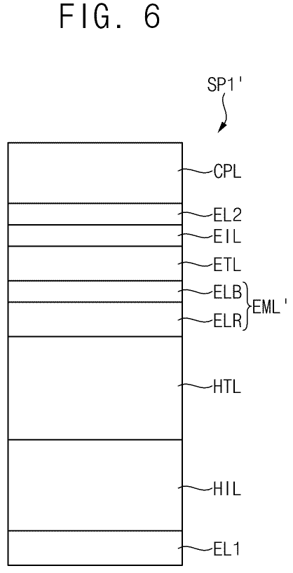

FIG. 4 is a view illustrating the fluid flow in the processing device according to a comparative embodiment. FIG. 5 is a view illustrating the substrate disposed in the processing device of FIG. 4. FIG. 6 is a view illustrating a sub pixel manufactured by the processing device of FIG. 4.

Referring to FIG. 4, a processing device DE′ may not include the first remover EX1 and the second remover EX2.

For convenience of explanation, other components may be omitted and a fluid flow F1′, F2′, and/or F3′ of a substrate SUB′ and processing space PS' are shown.

As described herein, the processing device DE′ may include a vacuum chamber CH1′ in which the drying process and/or the curing process may be performed.

In an embodiment, while the drying process and/or the curing process is in progress, the solvent and/or the light-emitting material included in the ink may be vaporized (or liquefied).

In the vacuum chamber CH1′, a first fluid flow F1′ in which the vaporized (or liquefied) solvent and/or the foreign material may move to the side of the substrate SUB′, a second fluid flow F2′ in which the foreign material may move to the upper part of the substrate SUB′, and a third fluid flow F3′ in which the foreign material may move to the lower part of the substrate SUB′ may occur.

Referring to FIG. 5, the substrate SUB′, which may be disposed in the processing device DE′, may include a plurality of pixels PX′. In an embodiment, each of the plurality of pixels PX′ may include a first sub pixel SP1′, a second sub pixel SP2′, and a third sub pixel SP3′. However, the disclosure is not limited thereto. For example, each of the plurality of pixels PX′ may include two or four or more sub pixels.

Each of the first sub pixel SP1′, the second sub pixel SP2′, and the third sub pixel SP3′ may emit different color light. For example, the first sub pixel SP1′ may emit red light, the second sub pixel SP2′ may emit green light, and the third sub pixel SP3′ may emit blue light. However, the disclosure is not limited thereto. For example, each of the first sub pixel SP1′, the second sub pixel SP2′, and the third sub pixel SP3′ may emit a same color light (e.g., white light).

The second sub pixel SP2′ and the third sub pixel SP3′ may have a same stacked structure as the first sub pixel SP1′. Therefore, hereinafter, the following description will mainly describe the first sub pixel SP1′.

Referring to FIG. 6, in an embodiment, the first sub pixel SP1′ may include a first electrode EL1, a light-emitting layer EML′, and a second electrode EL2 that may be sequentially stacked. Holes of the first electrode EL1 and electrons of the second electrode EL2 may meet in the light-emitting layer EML′ and light may be emitted.

A functional layer may be further disposed between the first electrode EL1 and the second electrode EL2. In an embodiment, the functional layer may include a hole injection layer HIL, a hole transport layer HTL, an electron transport layer ETL, and/or an electron injection layer EIL. In an embodiment, the hole injection layer HIL may inject the hole, the hole transport layer HTL may transport the hole to the light-emitting layer EML′, the electron transport layer ETL may inject the electron, and the electron injection layer EIL may transport the electron to the light-emitting layer EML′. However, the disclosure is not limited thereto. For example, layers included in the stacked structure of the first sub pixel SP1′ may be changed, omitted, and/or added. For example, the first sub pixel SP1′ may further include a capping layer CPL on the second electrode EL2. The capping layer CPL may reduce or prevent damage to the second electrode EL2 during post-processing.

As shown of FIG. 5, in the vacuum chamber CH1′, the foreign material may move into the first fluid flow F1′, the second fluid flow F2′, and/or the third fluid flow F3′.

In this case, the light-emitting layer EML′ included in the first sub pixel SP1′ may include a first light-emitting layer ELR and a second light-emitting layer ELB. In an embodiment, the first light-emitting layer ELR may include a red light-emitting material. In an embodiment, the second light-emitting layer ELB may include a blue light-emitting material. In this case, color light that is a mixture of red light and blue light may be emitted from the first sub pixel SP1′. Accordingly, display quality (e.g., color mixing, reduced luminous efficiency, or the like.) of the display device may deteriorate.

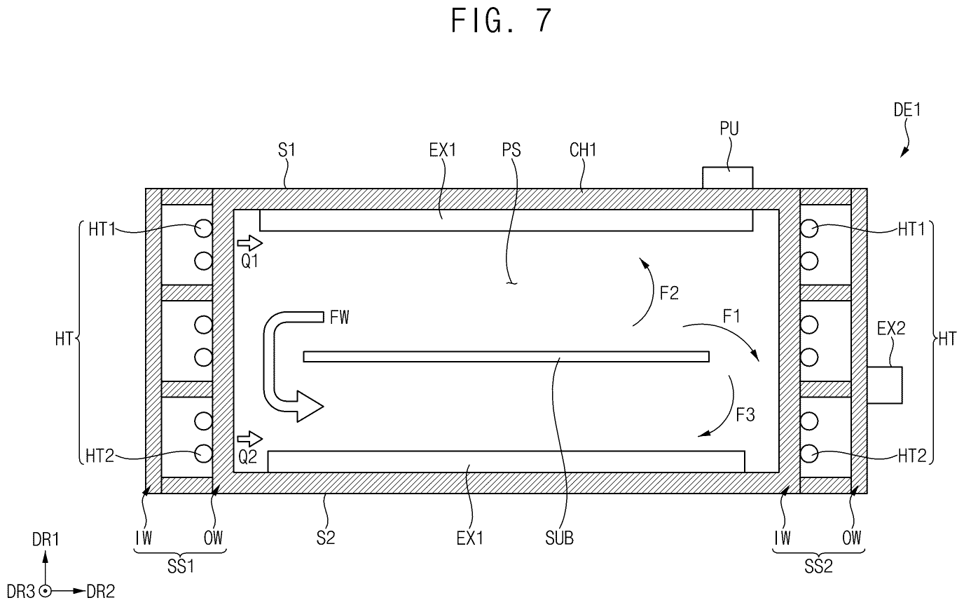

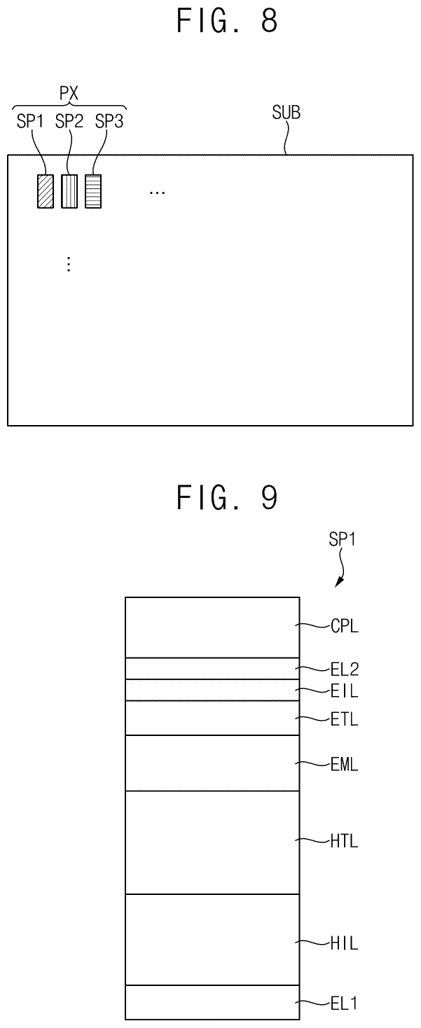

FIG. 7 is a view illustrating the fluid flow in the processing device of FIG. 1. FIG. 8 is a view illustrating the substrate disposed in the processing device of FIG. 1. FIG. 9 is a view illustrating the sub pixel manufactured by the processing device of FIG. 1.

Referring to FIG. 7, the processing device DE1 according to embodiments of the disclosure may include the first remover EX1 and the second remover EX2.

Hereinafter, repetitive descriptions of the substrate processing apparatus DE1′ described with reference to FIG. 1, FIG. 2, and FIG. 3 may be omitted or simplified.

As described herein, the processing device DE1 may include the vacuum chamber CH1 and may perform the drying process and/or the curing process.

In the vacuum chamber CH1, a first fluid flow F1 in which the vaporized (or liquefied) solvent and/or the light-emitting material (i.e., the foreign material) may move to the side of the substrate SUB, a second fluid flow F2 in which the foreign material may move to the upper part of the substrate SUB, and a third fluid flow F3 in which the foreign material may move to the lower part of the substrate SUB may occur. As shown of FIG. 7, a fluid flow FW in the direction from the upper part to lower part of the vacuum chamber CH1 may be more influential than the second fluid flow F2 and/or the third fluid flow F3.

In an embodiment, the fluid flow FW directed from the upper part of the processing space PS to the lower part of the processing space PS may be due, at least in part, to the temperature of the second heater HT2 being less than the temperature of the first heater HT1, and at least in part to the suction pressure applied by the second remover EX2. That is, the fluid flow FW may be a path of the foreign material, and the foreign material may be effectively removed from the processing space PS.

Referring to FIG. 8, the substrate SUB disposed in the processing device DE1 may include the plurality of pixels PX. In an embodiment, each of the plurality of pixels PX may include a first sub pixel SP1, a second sub pixel SP2, and a third sub pixel SP3. However, the disclosure is not limited thereto.

Each of the first sub pixel SP1, the second sub pixel SP2, and the third sub pixel SP3 may emit different color lights. For example, the first sub pixel SP1 may emit red light, the second sub pixel SP2 may emit green light, and the third sub pixel SP3 may emit blue light. However, the disclosure is not limited thereto. For example, the first sub pixel SP1, the second sub pixel SP2, and the third sub pixel SP3 may each emit the same color light (e.g., white light).

The second sub pixel SP2 and the third sub pixel SP3 may have a same stacked structure as the first sub pixel SP1. Therefore, hereinafter, the following description will mainly describe the first sub pixel SP1′.

Referring to FIG. 9, in an embodiment, the first sub pixel SP1 may include a first electrode EL1, a light-emitting layer EML, and a second electrode EL2 that may be sequentially stacked. Holes of the first electrode EL1 and electrons of the second electrode EL2 may meet in the light-emitting layer EML′ and light may be emitted by the first sub pixel SP1.

A functional layer may be further disposed between the first electrode EL1 and the second electrode EL2. As described herein, in an embodiment, the functional layer may include the hole injection layer HIL, the hole transport layer HTL, the electron transport layer ETL, and/or the electron injection layer EIL. However, the disclosure is not limited thereto. For example, layers included in the stacked structure of the first sub pixel SP1 may be changed, omitted, and/or added. As described herein, in an embodiment, the first sub pixel SP1 may further include the capping layer CPL on the second electrode EL2.

As shown of FIG. 7, in the vacuum chamber CH1′, the foreign material may move into the first fluid flow F1, the second fluid flow F2, and/or the third fluid flow F3.

As described herein with reference to FIG. 1, FIG. 2, and FIG. 3, the foreign material moving along the first fluid flow F1 may be removed by the second remover EX2. In addition, the foreign material moving along the second fluid flow F2 and/or the third fluid flow F3 may be removed by the first remover EX1.

As described herein, the first heating amount Q1 of the first heater HT1 may be greater than the second heating amount Q2 of the second heater HT2. Accordingly, the fluid flow FW may be formed in the direction from the upper part to the lower part of the vacuum chamber CH1. Accordingly, a portion of the foreign material may be removed by the second remover EX2 along the fluid flow FW.

Accordingly, as shown of FIG. 9, the first sub pixel SP1 may be formed to include the desired light-emitting layer EML.

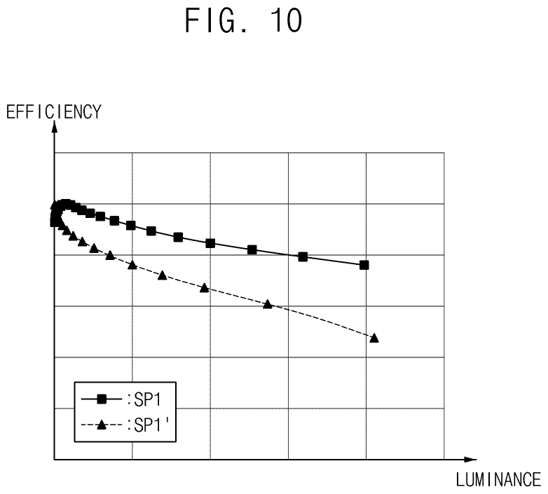

FIG. 10 is a view illustrating an effect of the processing device of FIG. 1.

In an embodiment, in FIG. 10, the X-axis represents luminance and the Y-axis represents luminous efficiency.

The luminance may refer to a degree to which light is emitted from a light source. As the luminance increases, the light emitted by the display device may be displayed clearly in bright ambient environments, such as the outdoors in daylight hours. The unit of luminance is may candela (Cd/m²).

In an example, the luminance of the first sub pixel SP1′ formed by the processing device DE′ of FIG. 4 may be about 3.4 Cd/m². In an embodiment, the luminance of the first sub pixel SP1 formed by the processing device DE1 of FIG. 7 may be about 17.8 Cd/m².

In other words, the light-emitting layer (e.g., the light-emitting layer EML′ of FIG. 6) manufactured by the processing device DE′ according to the comparative embodiment may include an unintended light-emitting material (e.g., blue color light-emitting material), as the foreign material moves within the vacuum chamber CH1′. Accordingly, the luminous efficiency of the substrate SUB′ may decrease.

On the other hand, as the processing device removes the moving foreign material by the first remover EX1 and the second remover EX2, the light-emitting layer (e.g., the light-emitting layer of FIG. 9) may be free of the unintended light-emitting material. Accordingly, the luminous efficiency may be enhanced or increased.

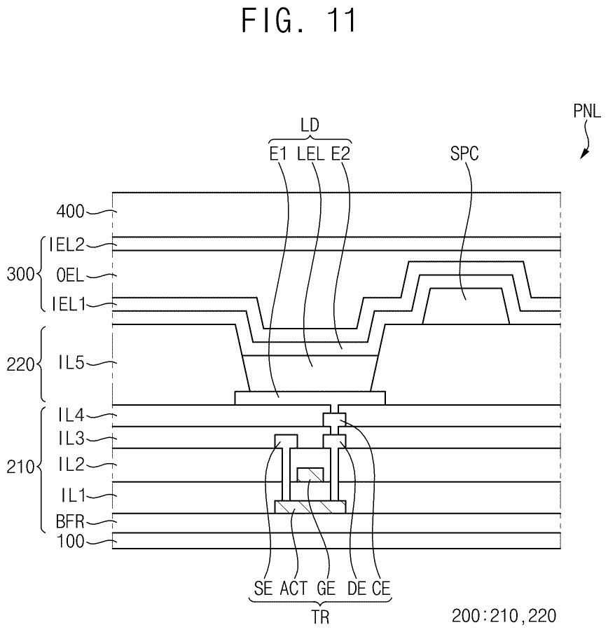

FIG. 11 is a view illustrating a display device formed using the processing device of FIG. 1.

Referring to FIG. 11, the display device may include a display panel PNL. The display panel PNL may include a substrate 100, a display device layer 200, an encapsulation layer 300, and a cover substrate 400. The display device layer 200 may include a circuit device layer 210 and a light-emitting device layer 220.

The circuit device layer 210 may be disposed on the substrate 100. The circuit device layer 210 may include a buffer layer BFR, at least one transistor TR, a connection electrode CE, a first insulating layer IL1, a second insulating layer IL2, a third insulating layer IL3, and a fourth insulating layer IL4. The transistor TR may include an active layer ACT, a gate electrode GE, a source electrode SE, and a drain electrode DE. The light-emitting device layer 220 may be disposed on the circuit device layer 210. The light-emitting device layer 220 may include a fifth insulating layer IL5, a spacer SPC, and at least one light-emitting diode LD. The light-emitting diode LD may include a first electrode E1, a light-emitting layer LEL, and a second electrode E2. For example, each of the first electrode E1, the light-emitting layer LEL, and the second electrode E2 may correspond to the first electrode EL1, the light-emitting layer EML′, and the second electrode EL2 of FIG. 6. In addition, each of the first electrode E1, the light-emitting layer LEL, and the second electrode E2 may correspond to the first electrode EL1, the light-emitting layer EML, and the second electrode EL2 of FIG. 9.

The substrate 100 may be an insulating substrate made of a transparent material. The substrate 100 may include, for example, glass or plastic.

The buffer layer BFR may be disposed on the substrate 100. The buffer layer BFR may inhibit or prevent metal atoms or impurities from diffusing from the substrate 100 to the active layer ACT.

The active layer ACT may be disposed on the buffer layer BFR. The active layer ACT may be divided into a source region and a drain region, which may be doped with impurities, and a channel region disposed between the source region and the drain region.

The first insulating layer IL1 may be disposed on the buffer layer BFR. The first insulating layer IL1 may be disposed on the active layer ACT. For example, the first insulating layer IL1 may cover the active layer ACT and may be formed to have substantially a same thickness along a profile of the active layer ACT. However, the disclosure is not limited thereto. For example, the first insulating layer IL1 may include an inorganic material.

The gate electrode GE may be disposed on the first insulating layer IL1. In an embodiment, the gate electrode GE may overlap the channel region of the active layer ACT.

The second insulating layer IL2 may be disposed on the first insulating layer IL1. The second insulating layer IL2 may be disposed on the gate electrode GE. For example, the second insulating layer IL2 may cover the gate electrode GE and may be disposed to have substantially the same thickness along the profile of the gate electrode GE. However, the disclosure is not limited thereto. For example, the second insulating layer IL2 may include an inorganic material.

The source electrode SE and the drain electrode DE may be disposed on the second insulating layer IL2. The source electrode SE may contact the source region of the active layer ACT through a first contact hole formed in the first insulating layer IL1 and the second insulating layer IL2. The drain electrode DE may contact the drain region of the active layer ACT through a second contact hole formed in the first insulating layer IL1 and the second insulating layer IL2.

The third insulating layer IL3 may be disposed on the second insulating layer IL2. The third insulating layer IL3 may be disposed on the source electrode SE and the drain electrode DE. For example, the third insulating layer IL3 may cover the source electrode SE and the drain electrode DE, and may have a substantially flat top surface without creating steps due to the source electrode SE or the drain electrode DE. For example, the third insulating layer IL3 may include an organic material.

The connection electrode CE may be disposed on the third insulating layer IL3. The connection electrode CE may contact the source electrode SE or the drain electrode DE through a third contact hole formed in the third insulating layer IL3.

The fourth insulating layer IL4 may be disposed on the third insulating layer IL3. The fourth insulating layer IL4 may be disposed on the connection electrode CE. For example, the fourth insulating layer IL4 may cover the connection electrode CE and may have a substantially flat top surface without creating steps due to the source electrode SE or the drain electrode DE. For example, the fourth insulating layer IL4 may include an organic material.

The first electrode E1 may be disposed on the fourth insulating layer IL4. The first electrode E1 may be reflective or transparent. For example, the first electrode E1 may include metal.

The first electrode E1 may contact the connection electrode CE through a fourth contact hole formed in the fourth insulating layer IL4. Through this, the first electrode E1 may be connected to the transistor TR.

The fifth insulating layer IL5 may be disposed on the fourth insulating layer IL4, and an opening exposing a top surface of the first electrode E1 may be defined in the fifth insulating layer IL5. For example, the fifth insulating layer IL5 may include an organic material or an inorganic material.

The spacer SPC may be disposed on the fifth insulating layer IL5. For example, the spacer SPC may include organic or inorganic materials. The spacer SPC may maintain a gap between the encapsulation layer 300 and the substrate 100.

The spacer SPC may include a material different from the fifth insulating layer IL5. The spacer SPC may be formed after the fifth insulating layer IL5 is formed. However, embodiments according to the disclosure are not limited thereto, and the spacer SPC may include the same material as the fifth insulating layer IL5. For example, the fifth insulating layer IL5 and the spacer SPC may include an organic material such as polyimide. In another example, the fifth insulating layer IL5 and the spacer SPC may be formed simultaneously using a half-tone mask.

The light-emitting layer LEL may be disposed on the first electrode E1. The light-emitting layer LEL may be disposed in the opening formed in the fifth insulating layer IL5. As described herein, the light-emitting layer LEL may have a multi-layer structure including the hole injection layer, the hole transport layer, the organic light-emitting layer, the electron transport layer, and the electron injection layer. The organic light-emitting layer may include a light-emitting material.

The second electrode E2 may cover the light-emitting layer LEL and may be disposed on the fifth insulating layer IL5 and the spacer SPC. In an embodiment, the second electrode E2 may have a plate shape. In addition, the second electrode E2 may be transparent or reflective. For example, the second electrode E2 may include metal.

The encapsulation layer 300 may be disposed on the light-emitting device layer 220. The encapsulation layer 300 may inhibit or prevent moisture and oxygen from penetrating into the light-emitting diode LD from the outside. For example, the encapsulation layer 300 may include a first inorganic encapsulation layer IEL1, an organic encapsulation layer OEL, and a second inorganic encapsulation layer IEL2.

The first inorganic encapsulation layer IEL1 may be disposed on the second electrode E2 with substantially a same thickness along a profile of the second electrode E2. The organic encapsulation layer OEL may be disposed on the first inorganic encapsulation layer IEL1 and may have a substantially flat top surface without creating steps due to the first inorganic encapsulation layer IEL1. The second inorganic encapsulation layer IEL2 may be disposed on the organic encapsulation layer OEL.

The cover substrate 400 may be disposed on the encapsulation layer 300. For example, the cover substrate 400 may include rigid glass, or the like. For another example, the cover substrate 400 may include a flexible polymer resin. As another example, the cover substrate 400 may be a film with a multi-layer structure. For example, the multi-layer structure may be a structure in which organic films and inorganic films are arranged alternately. However, the disclosure is not limited thereto.

For example, the organic light-emitting device included in the display device may be formed by an inkjet method. The inkjet method may include a process (e.g., the drying process and/or the curing process) for removing the solvent from the ink on the substrate 100. The process (e.g., the drying process and/or the curing process) may be performed by the processing device DE1 described with reference to FIG. 1, FIG. 2, and FIG. 3.

As described herein, the processing device DE1 may include the plurality of heaters HT disposed between the inner wall IW and the outer wall OW. Accordingly, the processing device DE1 may remove foreign material generated during thin film formation by heating.

In addition, the processing device DE1 may further include a first remover EX1 disposed in the processing space PS of the vacuum chamber CH1. Accordingly, the processing device DE1 may adsorb and remove the foreign material in the liquid form.

In addition, the processing device DE1 may be connected to the second remover EX2 disposed outside the vacuum chamber CH1, and may further include the connection pipe CT penetrating the inner wall IW and the outer wall OW of the vacuum chamber CH1. The connection pipe CT may provide a path for the fluid to move from the processing space PS to the second remover EX2. Accordingly, the processing device DE1 may exhaust the gaseous foreign material.

In addition, the plurality of heaters HT may include the first heater HT1 and the second heater HT2. The first heater HT1 may be disposed on the first side S1. The second heater HT2 may be disposed on the second side S2. The first heating amount Q1 of the first heater HT1 may be greater than the second heating amount Q2 of the second heater HT2. A fluid flow may be induced by the temperature difference. Accordingly, the foreign material may be removed along the fluid flow due to the temperature difference.

Embodiments of the present invention should not be construed as being limited to the disclosure. Rather, embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A processing device for processing a substrate comprising:
a vacuum chamber including a processing space including an inner wall disposed adjacent to the processing space and an outer wall disposed on and spaced apart from the inner wall; and
a plurality of heaters disposed between the inner wall and the outer wall.

2. The processing device of claim 1, further comprising:
a first remover disposed in the processing space of the vacuum chamber,
wherein the first remover includes:
a mesh network; and
an absorbent disposed in the mesh network.

3. The processing device of claim 2, wherein the absorbent includes at least one of charcoal or a porous material.

4. The processing device of claim 2, wherein the first remover adsorbs an organic material.

5. The processing device of claim 2, wherein the processing space is defined by a first side and a second side facing each other in a first direction, at least one side wall extending between the first side and the second side, and
the first remover is disposed on each of the first side and the second side facing each other in the first direction in the vacuum chamber.

6. The processing device of claim 1, wherein the processing space defined by a first side and a second side facing each other in a first direction, a first side wall and a second side wall facing a second direction crossing the first direction, a third side wall and a fourth side wall facing a third direction crossing each of the first direction and the second direction,
the plurality of heaters include a first heater and a second heater,
the first heater is disposed adjacent to the first side, and
the second heater is disposed adjacent to the second side.

7. The processing device of claim 6, wherein the first heater is configured to apply a first heating amount and the second heater is configured to apply a second heating amount less than the first heating amount.

8. The processing device of claim 1, further comprising:
a second remover disposed outside the vacuum chamber; and
a connection pipe connected to the second remover, penetrating the outer wall and the inner wall of the vacuum chamber, and providing a path for fluid in the processing space to move from the processing space.

9. The processing device of claim 8, wherein the fluid includes an organic material.

10. The processing device of claim 8, wherein the processing space defined by a first side and a second side facing each other in a first direction,
the first side of the vacuum chamber is disposed on the second side, and
the second remover is connected to the connection pipe adjacent to the second side.

11. A processing device for processing a substrate comprising:
a vacuum chamber including a processing space defined by a first side and a second side facing each other in a first direction, a first side wall and a second side wall facing a second direction crossing the first direction, a third side wall and a fourth side wall facing a third direction crossing each of the first direction and the second direction, wherein each of the first side wall, the second side wall, the third side wall, and the fourth side wall include an inner wall disposed adjacent to the processing space and an outer wall disposed on and spaced apart from the inner wall;
a plurality of heaters disposed between the inner wall and the outer wall; and
a stage disposed between the first side and the second side in the processing space.

12. The processing device of claim 11, further comprising:
a first remover disposed in the processing space of the vacuum chamber,
wherein the first remover includes:
a mesh network; and
an absorbent disposed in the mesh network.

13. The processing device of claim 12, wherein the absorbent includes at least one of charcoal or a porous material.

14. The substrate processing device of claim 12, wherein the first remover adsorbs an organic material.

15. The processing device of claim 13, wherein the first remover is disposed on each of the first side and the second side facing each other in the first direction in the vacuum chamber.

16. The processing device of claim 11, wherein the plurality of heaters include a first heater and a second heater,
the first heater is disposed adjacent to the first side,
the second heater is disposed adjacent to the second side, and
the first heater is configured to apply a first heating amount and the second heater is configured to apply a second heating amount different than the first heating amount.

17. The processing device of claim 11, further comprising:
a second remover disposed outside the vacuum chamber; and
a connection pipe connected to the second remover, penetrating the outer wall and the inner wall of the vacuum chamber, and providing a path for fluid in the processing space to move from the processing space.

18. The processing device of claim 17, wherein the first side of the vacuum chamber is disposed on the second side, and
the second remover is connected to the connection pipe adjacent to the second side.

19. A processing device for processing a substrate comprising:
a vacuum chamber including a processing space defined by a first side and second side facing each other in a first direction and at least one side wall extending between the first side and the second side, the at least one side wall including an inner wall disposed adjacent to the processing space and an outer wall disposed on and spaced apart from the inner wall; and
a plurality of heaters disposed between the inner wall and the outer wall and including a first heater disposed adjacent to the first side and a second heater disposed adjacent to the second side.

20. The processing device of claim 19, further comprising:
a first remover disposed on each of the first side and the second side facing each other in the first direction in the vacuum chamber;
a second remover disposed outside the vacuum chamber; and
a connection pipe connected to the second remover, penetrating the outer wall and the inner wall of the vacuum chamber.
